(19) United States
(12) Patent Application Publication
(10) Pub. No.: US 2012/0085388 A1
(43) Pub. Date: Apr. 12, 2012

(54) DUAL TOWER SOLAR TRACKER SYSTEM

(76) Inventor: William L. French, SR., Lexington, MA (US)

(21) Appl. No.: 13/226,073

(22) Filed: Sep. 6, 2011

Related U.S. Application Data
(63) Continuation of application No. 13/092,809, filed on Apr. 22, 2011.
(60) Provisional application No. 61/477,354, filed on Apr. 20, 2011.
(60) Provisional application No. 61/327,496, filed on Apr. 23, 2010.

(51) Int. Cl. H01L 31/052

(52) U.S. Cl. 136/246

(57) ABSTRACT

Energy collection systems, such as solar power generation systems, are useful for many applications. Existing support structures for solar panels are either static or arranged on a vertical pole or other assembly that enables rotation of the solar panels to track the sun about one or two axes. An embodiment of the present invention includes a multi-tower assembly, such as a dual tower assembly, that supports a solar panel assembly having a lower height-to-width ratio of the solar panel assembly than may be supported by a single tower design and includes a mount configured to rotate upon which the dual tower assembly is supported. A base support structure that may support the dual tower and solar panel assembly may be provided such that the system may be mounted on a ground treatment assembly on an unstable ground, such as a landfill, or other ground surface, to use the unstable ground as a venue for producing renewable energy.

### RELATED APPLICATIONS

This Application is a Continuation of application Ser. No. 13/092,809, filed on Apr. 22, 2011, which claims the benefit of U.S. Provisional Application No. 61/477,354 filed on Apr. 20, 2011, entitled “Dual Tower Solar Tracker System” by William L. French, Sr., and also claims the benefit of U.S. Provisional Application No. 61/327,496, entitled “Dual Tower Solar Tracker System” by William L. French, Sr., filed on Apr. 23, 2010. The entire teachings of the above applications are incorporated herein by reference.

### BACKGROUND OF THE INVENTION

Solar power systems are useful for converting solar energy into useful electric energy. Solar panels have been used in many applications, such as residential or standalone systems, to provide energy needed to operate electronics systems, such as emergency phone systems on the side of highways or dishwashers and televisions in residences. Multiple solar power generation systems may be deployed together to form solar panel farms to provide electrical power to grids that are used to distribute energy to entire communities.

### SUMMARY OF THE INVENTION

A solar power collection system comprising at least two towers configured to support a solar panel assembly and a base support structure, including a platform, configured to rotate the dual towers and enable the dual towers to rotate about a vertical axis. Alternative example embodiments of the present invention include a method of collecting solar power, including configuring at least two towers to support a solar power assembly and rotating a base support structure including a platform configured to rotate the dual towers, the rotation enabling the dual towers to rotate about a vertical axis. Further example embodiments of the present invention include a solar power collection system including a means for configuring at least two towers to support a solar power assembly and a means for rotating a base support structure interconnected to a platform, the platform configured to rotate the dual towers, causing the dual towers to rotate about a vertical axis.

### BRIEF DESCRIPTION OF THE DRAWINGS

The foregoing will be apparent from the following more particular description of example embodiments of the invention and as illustrated in the accompanying figures. The drawings are not necessarily to scale, emphasis instead being placed upon illustrating example embodiments of the present invention.

The accompanying figures, where like reference numerals refer to identical or functionally similar elements throughout the separate views and which together with the detailed description below are incorporated in and form part of the Specification, serve to illustrate various embodiments and to explain various principles and advantages all in accordance with example embodiments of the present invention. The teachings of all patents, published applications and references cited herein are incorporated by reference in their entireties.

FIG. 1 is a front view of a dual tower solar tracker according to an embodiment of the present invention.

FIG. 2 is a side view of an example embodiment of a dual tower solar tracker system.

FIG. 3 is a top view of an example embodiment of the dual tower solar tracker system.

FIG. 4 is a front view of a base riser for a dual tower solar tracker system.

FIG. 5 is a diagram of a collection of dual tower solar trackers used together.

FIG. 6 is a flow chart that illustrates a method for performing example embodiments of the present invention.

FIG. 7 is a flow diagram of an embodiment of the present invention that illustrates an example process of the present invention.

### DETAILED DESCRIPTION OF THE DRAWINGS

A description of example embodiments of the invention follows. An embodiment of the present invention includes a dual tower assembly and system, where the “assembly” refers to the mechanical arrangements and the “system” refers to a combination of electrical and mechanical components used for structural and functional operation. It should be understood that the terms may be used interchangeably herein. The dual tower assembly may be configured to support solar panels, for example, and rotate the solar panels in multiple axes, including vertical and horizontal axes of rotation. The vertical axis of rotation allows the dual tower assembly to rotate the solar panels in an axis perpendicular to the ground (i.e., the Earth's surface local to the assembly on which the dual tower assembly is mounted) or other surface on which the dual tower assembly is mounted to track the sun on its east-to-west path during the day; and the horizontal axis of rotation allows the solar panels to track the sun's elevation from sunrise through sunset. Alternative example embodiments of the present invention enable the solar panels to rotate around the x-, y-, and z-axes (in roll, pitch, and yaw Cartesian coordinate system directions, or other coordinate system directions) at varying angles and degrees. Because the dual tower assembly has two towers, the entire tower assembly is mounted to a rotating platform, in some example embodiments, and driven by a motor or other actuating stimulus to rotate the entire assembly, including dual towers and solar panels, about its vertical axis.

In one embodiment, the solar panels may be folded in one or multiple directions on a single side of the dual tower assembly or on multiple sides of the dual tower assembly, such that two solar panels may be facing each other or facing away from each other in folded configurations. Hinges that are capable of supporting the weight and rotation of the solar panels are employed in a folding configuration assembly.

The base of the dual tower assembly provides sufficient ballast as to be able to maintain an upright position under extreme wind or weather conditions, and may include assembly components, such as outriggers or ground mounting elements, such as rods extending several feet into the ground, to maintain stability. Further, the dual tower solar tracker system may include inverters and energy storage, such as batteries, optionally physically positioned on the base between the dual towers or elsewhere. Cables or other elements may be included to transfer the electrical energy generated by the solar panels to location(s) away from the dual tower tracker system for storage or use.

Any forms of gears or other rotational elements may be employed to enable turning of the dual towers in a smooth manner or in a step-wise manner. A riser on which the dual tower assembly may be mounted, may also be provided, such as for use in areas having known environmental conditions for which solar panel systems should be raised, such as snowy regions or flood-prone regions.

Collections of solar panels may be provided and have a common energy storage facility or common energy transport capability, such as through cabling that travels serially or in parallel to each of the solar trackers.

It should be understood that the foregoing examples may similarly apply to other energy collection systems, such as wind turbine systems.

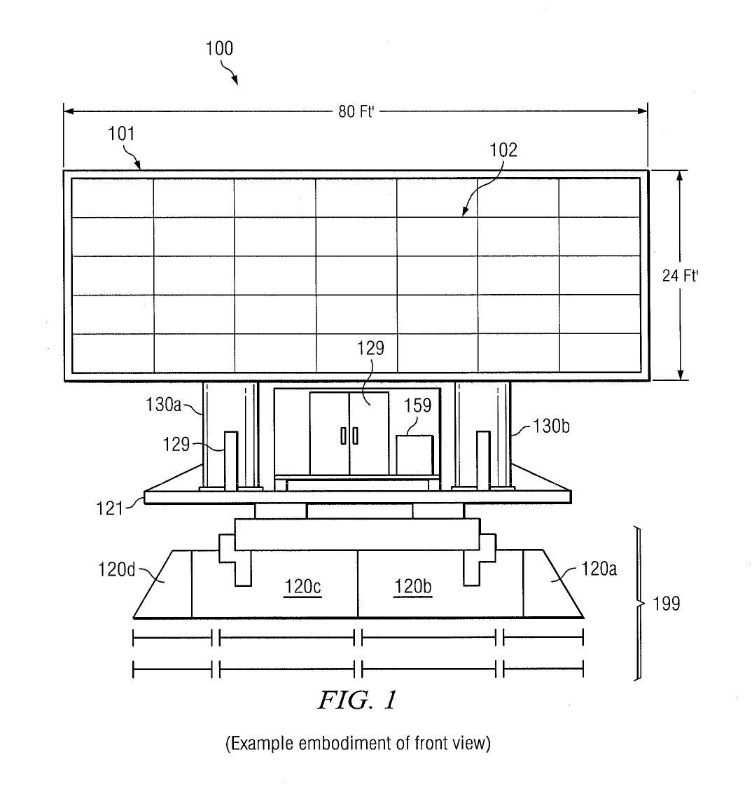

FIG. 1 is a diagram 100 of a front view of a dual tower solar tracker system. The diagram 100 includes example dimensions, such as 24 feet height and 80 feet width of a solar panel assembly; however, it should be understood that any size solar panel assembly may be accommodated by the dual tower assembly and system, assuming the dual towers are also appropriately sized and spaced. Mechanical and structural principles apply to supporting the solar panel assembly.

The dual tower assembly provides support that may not be captured by a single tower assembly, where the dual towers serve to provide a height-shortening feature and width-elongating feature of a solar panel array 101 that may not be accomplished with a single tower design. Because of the difference in dimensions compared to a single tower design, the dual tower design is much better for providing energy support in low angular solar conditions, such as at sunrise or sunset, where shadows cast by the lower height solar panels affect exposure to sunlight of solar panels behind them to a much lesser degree, or, with only short risers needed between each successive row of solar panels, each successive row has full access to sunlight during an entire day and in an area and riser heights much less than with taller solar panels.

The dual tower design lends itself to changing of solar panels 101 by simple coupling and decoupling of the solar panels 101 in any usual method used in the art, such as through bolt-on structures and the like. The example embodiment of FIG. 1 may couple or connect the photovoltaic (PV) solar panel 101 to a dual tower support brace 129 that may connect a first tower 130a and a second tower 130b. The first and second towers 130a-b may further be coupled, via linkage bolt systems or structurally interlaced elements, or other known methods of interlocking segments, to a precast structure created by the interconnected segmental precast segments 120a-d. Further example embodiments of the present invention may be connected using more or fewer precast segments to create the base structure as may be needed or desired based on the environment, location, and other factors for consideration in designing the dual tower base 199. Further example embodiments of the dual tower design may include a region on the base 121 between the dual towers in which an inverter 129 may be provided to convert electrical energy produced by the solar panels (not shown), where the inverter converts raw electrons provided by the solar panels into electrical energy that may be stored in storage elements 159, such as batteries (not shown), or may be put onto electrical conduction cables for delivery to a power grid or to a power plant.

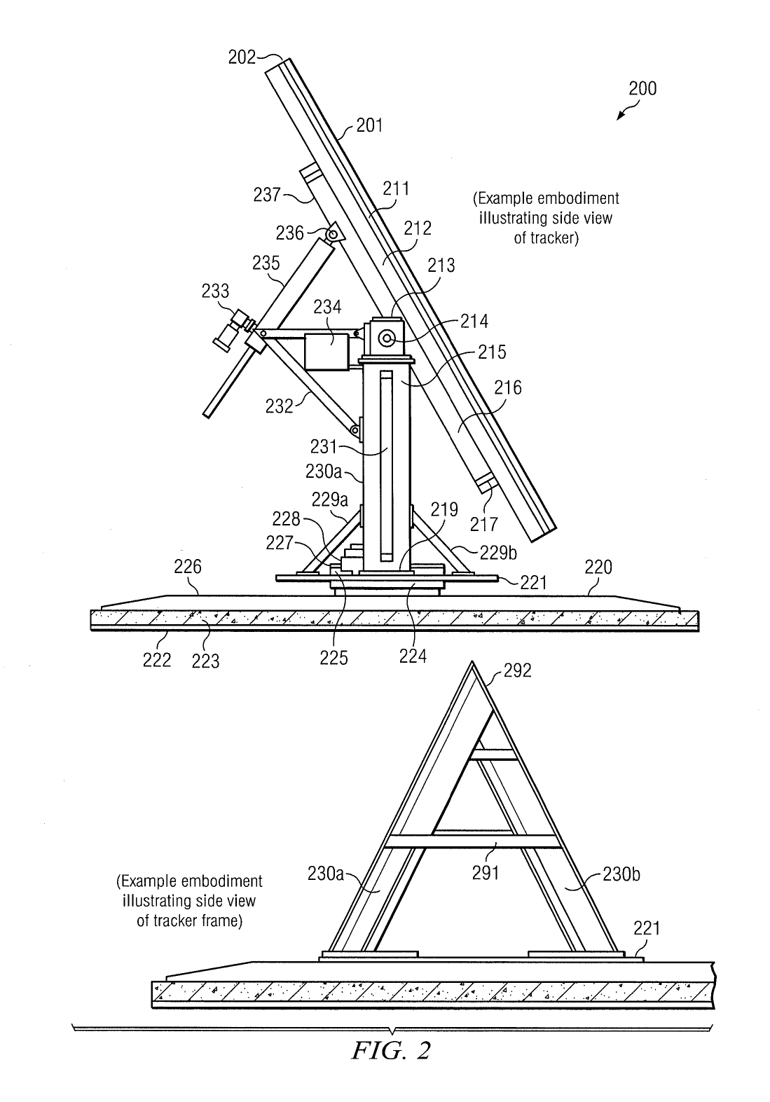

FIG. 2 is a diagram 200 of a side view of the dual tower design, which illustrates the dual towers, namely a first tower 230a and a second tower 230b, as coupled together at a base plate 221 and at an upper end 292, and, optionally, along the dual towers between the base and upper end 291. The structures provide lateral stiffnesses for the dual towers; other stiffnesses are provided by the materials, dimensions, support structures, and other features of the dual towers, such that the dual towers collectively provide sufficient stiffnesses to support the solar panels in various orientations and during various weather conditions, such as periods of high winds.

The diagram 200 of the tracker frame system may include a multitude of interconnected and/or coupled segments, structures, and elements, a few of which are explained directly below. The tracker assembly or system may be placed directly on the ground or surface, such as a stone surface 223, where a stabilization fabric 22 is placed below all of or some portion of the stone surface 223. Precast segments 220 may be placed, interconnected, or assembled on the ground surface using precast segmental concrete with low ground pressure ballast for minimal press or ground interference.

A base plate 221 may be linked with slewing gears and bearings 225, a drive gear 224, or alternative mechanisms for connecting the tower structures to the base structures; the slewing gears and bearings 225 and drive gear 224 may be interconnected or coupled to the base plate, which is itself coupled to the precast segments, via a bolt linkage system or interlocking element(s). A drive gear motor 228 may be operably interconnected to the drive gear 224 and located on or around the tracker system, such as encompassed by a service panel 227 for protecting the control system from external forces, such as inclement weather. The main frames 230a-b form a defining structure of the dual axis solar tracker assembly, where the main frames may connect with the solar panel 201 via at least one element, such as a horizontal beam 217, first vertical beam 216, and second vertical beam 212, and may be linked via an adjustable linkage bracket 211 and/or a pin-and-lock system connected with other elements of the tracker assembly. For a first tower (the second tower having a main frame as shown like the main frames 230a-b or similar in structure) may be attached or connected to the base plate via multiple interconnecting methods, for example via bolt linkage systems or dual tower support braces 229a-b, which provide additional structural support for the frames of the towers.

Further example embodiments of the present invention may include a solar collector 202 operably interconnected to the solar panel 201 via a solar collector pivot bracket 214 or linkage bracket with or without pin locking systems 213. The solar collector system may be further connected to a solar collector control box 234 via a screw jack, electric screw jack support system with linkage 232, and extra bracing support beam, for the main frame interconnected to the beams 216 and 217 to provide additional support based on internal or external forces acting on the dual tower tracker system. Such example embodiments may include additional linkage components as may be necessary to provide sound structural support for the tracker system, for example, including additional screw jack 235 and jack linkages 236 or other elements providing mechanisms for interlocking or linking components of the structural elements described herein or currently known in the art.

In one example embodiment, the dual towers may be folded to be parallel with a surface of its base or a ground surface such that, in an event of unusually high winds, the solar panel array may be laid effectively flat with the ground. Further, the dual tower may provide enabling hinge characteristics, such as solar collector center tilt control beam 237, either at the dual tower assembly or supporting hinging rotations of the solar panel structure such that each solar panel may be rotated inward toward or outward from other solar panel(s). Folding-up the solar panels during periods of non-use or periods of inclement weather adds longevity to the solar panels.

The dual tower assembly supports rotation of the solar panel array around vertical and horizontal axes such that the dual tower assembly may cause the solar panel array to track the sun for optimized solar collection and power conversion. A motor or other activation mechanism may be employed to rotate the solar panels around either axis. It should be understood that for ease of rotation around either the vertical or horizontal axes, the solar panel assembly is preferably balanced such that rotation is made mechanically possible with as little power as necessary. However, it should be understood that less than optimized rotational characteristics, such as an unbalanced mass configuration, may also be supported by the dual tower assembly.

Alternative example embodiments of the present invention may include the solar panel arrays being interconnected to the dual tower assembly system and may be configured to prove energy collected directly to the dual tower system, after such energy is converted, such that the dual tower system may be self-powered. Where an inverter converts raw electrons provided by the solar panels into electrical energy that may be stored in storage elements, such as batteries (not shown), or may be put onto electrical conduction cables for use by the same or separate dual tower systems.

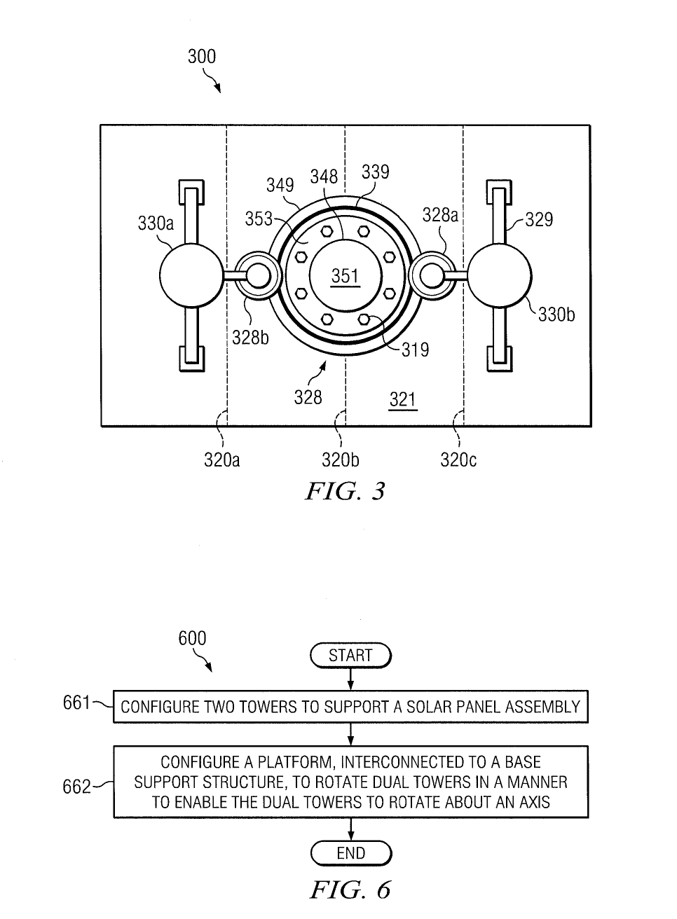

FIG. 3 is a diagram 300 of a top view that illustrates a rotational base having a main slewing gear 339 or series of slewing gears to enable rotation of a platform, on which the dual towers may be configured, or a rotational base, such as base plate 321, which may be created from a series of precast ballast segments 320a-c, to which the dual towers (not shown) may be mechanically coupled in a truss-supported arrangement. The dual towers may further be interconnected with the base plate, or a riser plate 349, via tower support connections 330a-b. As illustrated, there may be a single- or dual-motor design 328a-b that is connected to the rotating platform 348 such that the dual towers may rotate the solar assembly (not shown) in a 360°, or more or fewer degree, range.

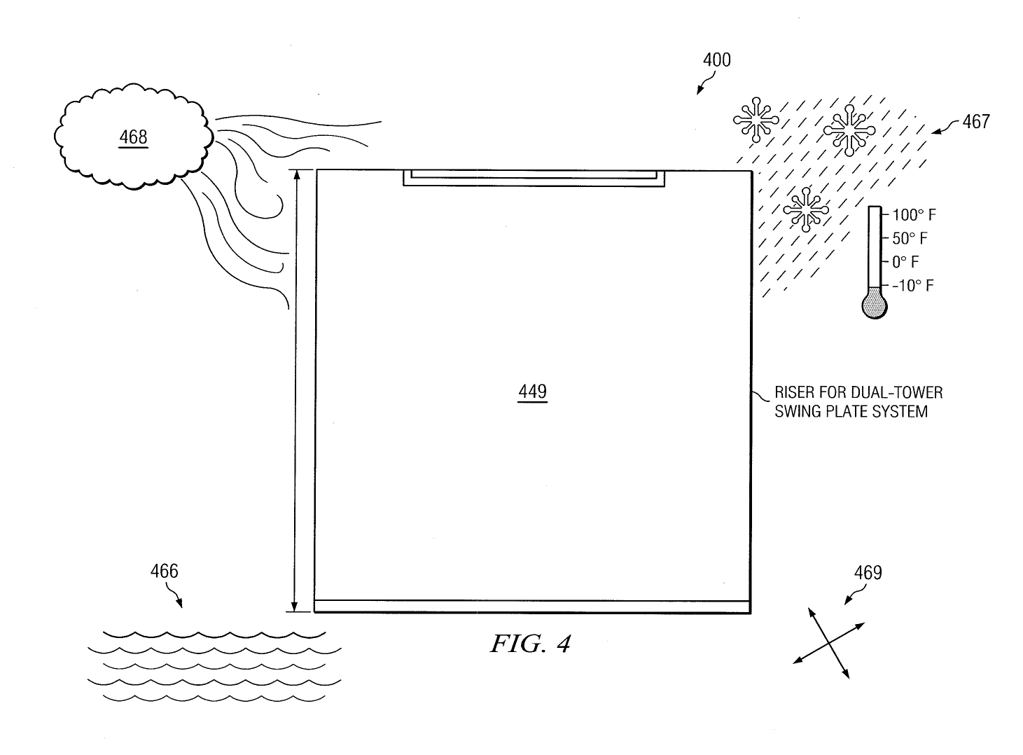

FIG. 4 is a diagram 400 that illustrates a side view of a base riser 449 of an example embodiment of the present invention that may be employed in environments in which inclement weather conditions occur, such as flooding 466, blizzard conditions 467, high winds 468, or earthquake conditions 469. The base of the twin tower (not shown) may be mechanically or structurally connected to the top of the riser 449, or the entire riser 449 may form a turntable type system. The dual towers or assembly or system may be mechanically or structurally connected to the riser on the sides of the riser or top of the riser.

It should be understood that, although described herein as a dual tower assembly, there may be more than two towers, such as three, four, or more towers, depending on size, configuration (e.g., width or height), or other parameters of the solar panel structure. In the case of having more than two towers, it should be understood that rotating the solar panels around a horizontal axis is different from a dual axis design since at least one of the solar panels would fold into a tower or multiple towers during rotation. Therefore, in the case of a three or more tower assembly, a truss system with axis hinge or other to a structure (not shown) that enables single-axis or universal-axes rotation is employed. In some embodiments, the multiple towers may be connected together by trusses or other stiffening members such that the towers act uniformly to support any rotation that may occur with the solar panel assembly and also support the solar panel assembly in any normal or unusual orientation.

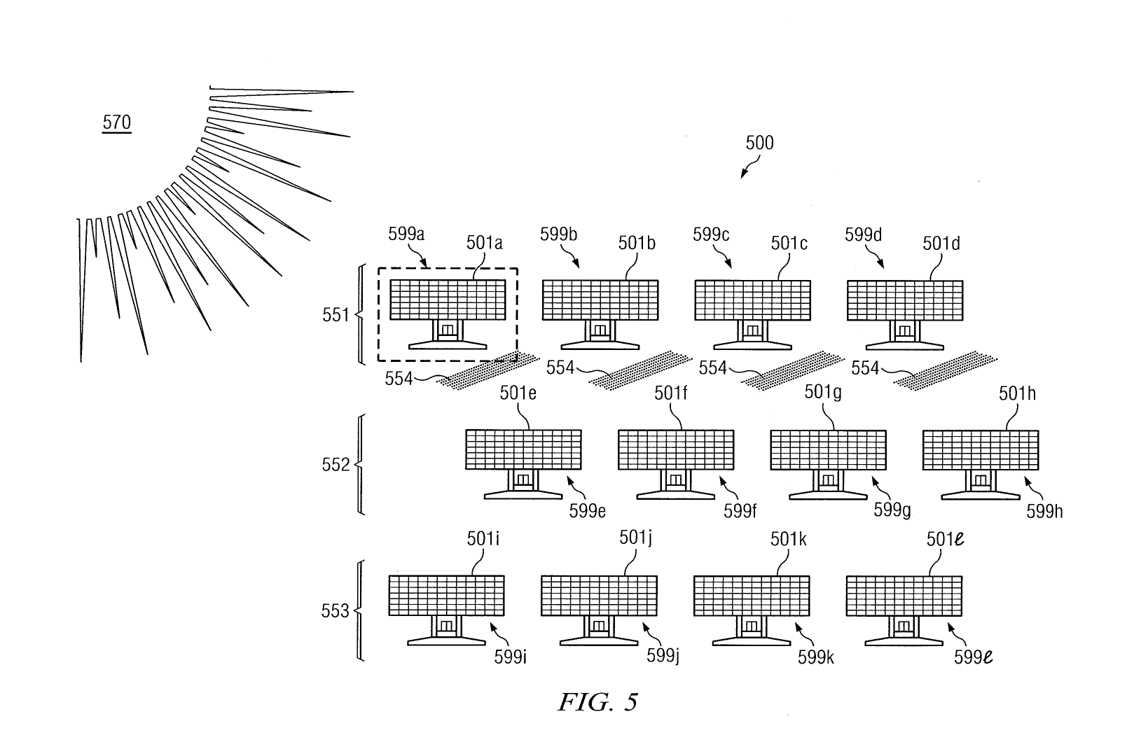

FIG. 5 is a diagram 500 that illustrates multiple dual tower solar tracker systems 599a-l that may be offset from each other spatially such that shadows 554 cast from the sun 570 by a first row 551 do not impact or minimally impact solar collection by a row of solar panels behind the first row, such as a second row of panels 552 or a third row of panels 553. Because the heights of the solar panels may be significantly lower with the dual tower tracker design as compared to a single tower tracker design, spacing between rows may be significantly reduced as compared to single tower designs that may not support the lower height, larger width configuration of the solar panels. Since there are two towers in the dual tower design, the base requires rotation for two-axis tracking of the sun; however, this added complexity may be worth the expense in some space-limited environments.

A base support structure, such as one disclosed in U.S. patent application Ser. No. 12/658,606, entitled “Segmented Ballast Base Support Structure and Rail and Trolley Structures for Unstable Ground” by William L. French, Sr. filed on Feb. 10, 2010, the entire teachings of which are incorporated herein by reference, may be employed to support the dual tower assembly for use on landfills, brownfields, or other unstable grounds.

Alternative example embodiments of the diagram 500 may include the multiple dual tower solar tracker systems being configured with mirrored backings (e.g., on the reverse side of the solar panel array) and/or mirrored base support structures, such that the reflection of light off of the mirrored structures of one system may be received by surrounding system(s).

FIG. 6 is a flow chart 600 of an embodiment of the present invention that illustrates a method of configuring a dual tower system. After beginning, the flow chart 600 configures two towers to support a solar panel assembly (661). The method of flow chart 600 further configures a platform, interconnected to a base support structure, to rotate dual towers in a manner enable the dual towers to rotate about an axis (662).

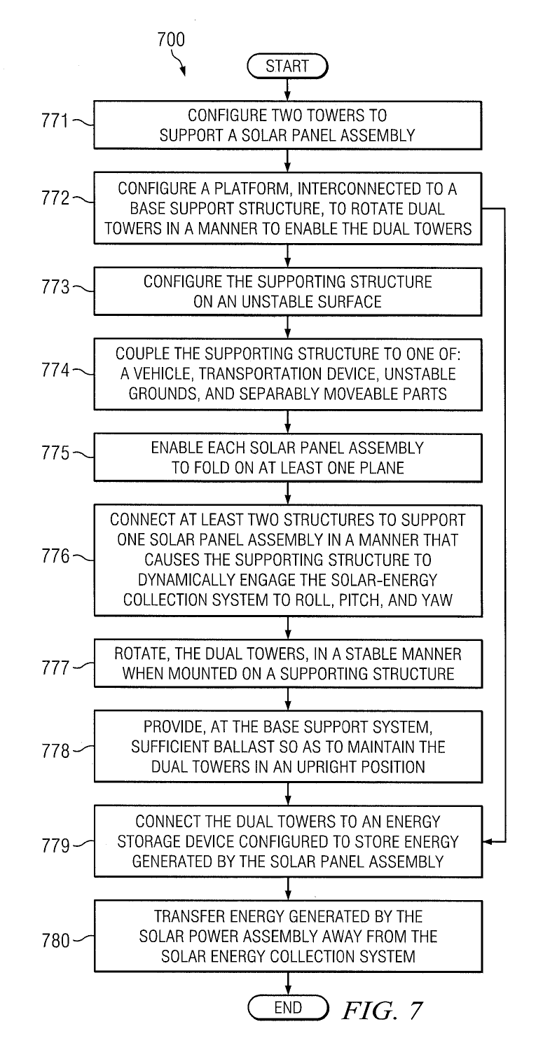

FIG. 7 is a flow diagram 700 of an embodiment of the present invention that illustrates a method of configuring or implementing a dual tower support system. After beginning, the method of the flow diagram 700 may configure two towers to support a solar panel assembly (771) and configure a platform, interconnected to a base support structure, to rotate dual towers in a manner enable the dual towers to rotate about an axis (772). The example method may further configure the supporting structure to operate on an unstable surface (773), where the supporting structure is coupled to one of: a vehicle, transportation device, unstable grounds, and separably moveable parts (774). The method 700 may further enable each solar panel assembly to fold on at least one plane, or axis (775). In other example embodiments of the flow diagram 700, the method may connect at least two structures to support one solar panel assembly in a manner that causes the supporting structure to dynamically engage the solar energy collection system to roll, pitch, and yaw (776). The method 700 may further rotate the dual towers in a stable manner when mounted on a supporting structure (777) and/or provide, at the base support system, sufficient ballast so as to maintain the dual towers in an upright position (778). Additional example embodiments of the flow diagram 700 may connect the dual towers to an energy storage device configured to store energy generated by the solar panel assembly (779) and/or transfer energy generate by the solar power assembly away from the solar energy collection system (780).

It should be known by one skilled in the art that the method of flow diagram 700 may be performed in any manner or order that may be useful to implement example embodiments of the present invention.

Alternative solar collector or system of solar collectors such as example embodiments of the dual axis solar tracker system of the present invention may be equipped with varying systems and units, such as non-ground penetrating support systems and low ground pressure support systems (e.g., support systems with limited foot print). Further example embodiments of such solar collectors may be incorporated into landfills, brownfields, and/or superfund sites that are beneficial locations for such example embodiments of the present invention but may be require support systems that are capable of being implemented in unstable ground, such as a segmented ballast support system. Details of the segmented ballast base support structure are described further in pending U.S. patent application Ser. No. 12/658,608 filed on Feb. 9, 2010, entitled “Segmented Ballast Base Support Structure and Rail and Trolley Structures for Unstable Ground” by William L. French, Sr. The entire teachings of which are incorporated herein by reference.

Alternative example embodiments of the present invention may be configured to withstand varying inclement external conditions, whether natural or man-made; for example, example embodiments may be earthquake resistant and capable of withstanding heavy winds. Further example embodiments of the present invention may be designed to provide various sizes and kilowatt power outputs, or other such outputs as are currently known or hereinafter developed for the use of solar power systems. The example embodiments may include wireless control systems that may be manual or automated for control of the solar tracking systems. The control system may further be enabled to be powered by direct electric connection, battery powered, or self-actuating based on the energy collected and converted from the solar tracking systems attached to the control systems.

Further example embodiments of the present invention may include a non-transitory computer readable medium containing instruction that may be executed by a processor, and, when executed, causes the processor to perform different functions, such as causing a control system to rotate solar panels in multiple axes and/or rotate a support structure or base in a manner as to rotate the connected solar panels. It should be understood that elements of the block and flow diagrams described herein may be implemented in software, hardware, firmware, or other similar implementation determined in the future. In addition, the elements of the block and flow diagrams described herein may be combined or divided in any manner in software, hardware, or firmware. If implemented in software, the software may be written in any language that may support the example embodiments disclosed herein. The software may be stored in any form of computer readable medium, such as random access memory (RAM), read only memory (ROM), compact disk read only memory (CD-ROM), and so forth. In operation, a general purpose or application specific processor loads and executes software in a manner well understood in the art. It should be understood further that the block and flow diagrams may include more or fewer elements, be arranged or oriented differently, or be represented differently. It should be understood that implementation may dictate the block, flow, and/or network diagrams and the number of block and flow diagrams illustrating the execution of embodiments of the invention.

While this invention has been particularly shown and described with references to example embodiments thereof, it will be understood by those skilled in the art that various changes in form and details may be made therein without departing from the scope of the invention encompassed by the appended claims.

What is claimed is:

1. An energy collection system comprising:
at least two towers configured to support an energy collection assembly; and
a base support structure including a platform configured to rotate the dual towers to enable the dual towers to rotate about a vertical axis.

2. The energy collection system of claim 1 wherein the energy collection system is a solar panel assembly or a wind turbine assembly.

3. The energy collection system of claim 1 wherein the supporting structure is positioned on an unstable surface via a surface treatment assembly.

4. The energy collection system of claim 3 wherein the supporting structure can be one of: a vehicle, transportation device, unstable grounds, and separably moveable parts.

5. The energy collection system of claim 1 wherein each energy collection assembly is configured to fold or rotate in at least one plane.

6. The energy collection system of claim 1 further comprising:
at least two structures, each structure being configured to support one energy collection assembly;
a base support system operably interconnected to a platform configured to enable rotation of the at least two structures about vertical, horizontal, or angled axes; and
a supporting structure configured to mount the dynamic energy collection assembly to the at least two structures.

7. The energy collection system of claim 1 wherein the at least two towers are further configured to rotate in a stable manner when mounted on the supporting structure.

8. The energy collection system of claim 1 wherein the base support system is further configured to provide sufficient ballast so as to maintain the at least two towers in an upright position in the presence of varying internal and/or external forces.

9. The energy collection system of claim 1 further comprising:
assembly components configured to maintain stability of mounted components, structures, and elements thereof;
at least one energy storage device configured to store energy generated by the solar panel assembly; and
a transfer unit configured to transfer the energy generate by the solar power assembly away from the solar energy collection system.

10. A method of collecting energy, the method comprising:
configuring at least two towers to support an energy collection assembly; and
rotating a base support structure including a platform configured to rotate the dual towers, the rotation enabling the dual towers to rotate about a vertical axis.

11. An energy collection system, comprising:
means for configuring at least two towers to support an energy collection assembly; and
means for rotating the dual towers about a vertical axis.
